(19) United States
(12) Patent Application Publication
(10) Pub. No.: US 2008/0025531 A1
(43) Pub. Date: Jan. 31, 2008

(54) Microphone amplifier

(75) Inventors: Tatsuya Suzuki, Saitama (JP); Yasuhiro Kaneta, Gunma (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD., Moriguchi-Shi (JP); Sanyo Semiconductor Co., Ltd., Ora-Gun (JP)

(21) Appl. No.: 11/878,440

(22) Filed: Jul. 24, 2007

(30) Foreign Application Priority Data
Jul. 25, 2006 (JP) 2006-201463

(51) Int. Cl. H04R 3/00; H03F 21/00; H03G 3/00

(52) U.S. Cl. 381/111; 330/278; 381/120

(57) ABSTRACT

With a microphone amplifier using an operational amplifier, there has been a problem that a sensitivity of the condenser microphone is reduced by an influence of a parasitic capacitance generated at an input terminal of the operational amplifier. This invention offers a microphone amplifier having a condenser microphone that converts a sound into a voltage signal, an operational amplifier having an inverting input terminal to which the voltage signal from the condenser microphone is applied and a non-inverting input terminal to which a direct current bias voltage is applied, a capacitor connected between the inverting input terminal and an output terminal of the operational amplifier, and a resistor connected between the inverting input terminal and the output terminal of the operational amplifier.

### CROSS-REFERENCE OF THE INVENTION

This application claims priority from Japanese Patent Application No. 2006-201463, the content of which is incorporated herein by reference in its entirety.

### BACKGROUND OF THE INVENTION

1. Field of the Invention

This invention relates to a microphone amplifier that amplifies an audio signal from a condenser microphone that converts a sound into a voltage signal, specifically to a microphone amplifier that reduces influence of a parasitic capacitance generated when the microphone amplifier is incorporated into an integrated circuit.

2. Description of the Related Art

The condenser microphone that converts the sound into the voltage signal is well known. The condenser microphone is composed of a capacitor. When a capacitance C of the capacitor is modified by the sound while an electric charge Q stored in the capacitor is kept constant, a voltage V between both ends of the capacitor varies in accordance with a formula: Q=CV.

FIG. 2 shows principles of operation of the condenser microphone. A condenser microphone 10 made of a pair of capacitor electrodes and a dielectric interposed between them is formed on a semiconductor die. A bias voltage source 20 is connected between the pair of capacitor electrodes through a resistor 30. A capacitance of the condenser microphone 10 varies slightly when an external sound (sound pressure) is applied to the pair of capacitor electrodes to cause a fine vibration. A slight variation in an output signal V of the condenser microphone 10 is caused as a result. An audio output signal is obtained by amplifying the output signal V with a microphone amplifier.

It is conceived to use an operational amplifier as the microphone amplifier that amplifies the audio signal from the condenser microphone.

The prior art is disclosed in Japanese Patent Application Publication Nos. 2000-236383 and 2001-102875.

With the microphone amplifier using the operational amplifier described above, however, there is a problem that a sensitivity of the condenser microphone is reduced by an influence of a parasitic capacitance generated at an input terminal of the operational amplifier.

When the operational amplifier is incorporated into an integrated circuit, a parasitic capacitance caused at a pad, a gate capacitance of an initial stage transistor and the like in the integrated circuit is seen from the input terminal of the operational amplifier.

The parasitic capacitance attenuates the audio signal from the condenser microphone. To describe concretely, the audio signal from the condenser microphone is divided and shared by the capacitance of the condenser microphone and the parasitic capacitance.

And the divided audio signal is amplified by the operational amplifier in a subsequent stage. At that time, a level of the audio signal is reduced because the audio signal is divided. Increasing a gain of the operational amplifier is required to compensate the reduction in the level of the audio signal. When the gain of the operational amplifier is increased, however, there arises another problem that is an increase in a floor noise.

### SUMMARY OF THE INVENTION

This invention is directed to solve the problems addressed above, and offers a microphone amplifier having a condenser microphone that converts a sound into a voltage signal, an operational amplifier having an inverting input terminal to which the voltage signal from the condenser microphone is applied and a non-inverting input terminal to which a direct current bias voltage is applied, a capacitor connected between the inverting input terminal and an output terminal of the operational amplifier, and a resistor connected between the inverting input terminal and the output terminal of the operational amplifier. Even when a parasitic capacitance is attached to the inverting input terminal of the operational amplifier, it exerts no influence because an electric potential at the inverting input terminal is fixed at a predetermined electric potential due to a feedback operation of the operational amplifier.

### BRIEF DESCRIPTION OF THE DRAWINGS

FIG. 1 shows a microphone amplifier according to an embodiment of this invention.

FIG. 2 shows principles of operation of a condenser microphone.

### DETAILED DESCRIPTION OF THE INVENTION

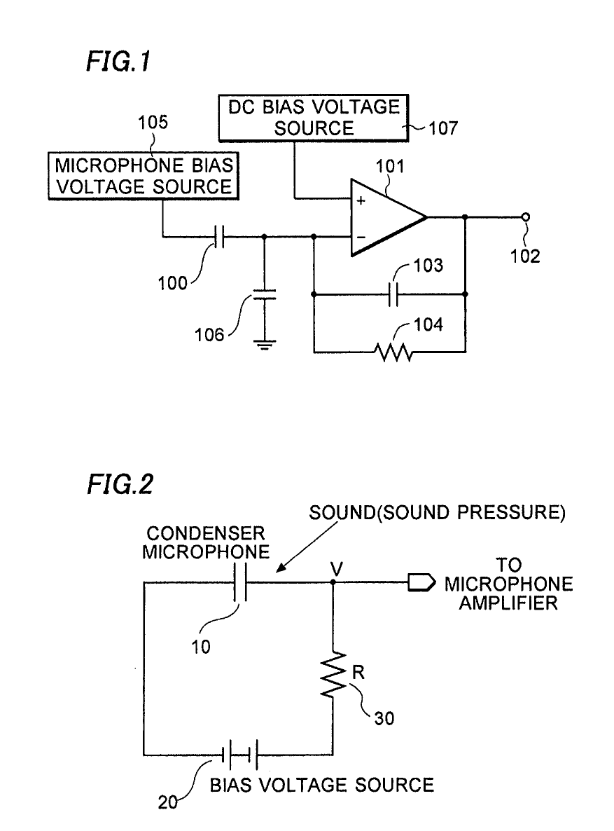

An embodiment of this invention is described in detail, referring to FIG. 1. FIG. 1 shows a microphone amplifier of a condenser microphone according to the embodiment.

The microphone amplifier shown in FIG. 1 has a condenser microphone 100 that converts a sound into a voltage signal, an operational amplifier 101 having an inverting input terminal (−) to which the voltage signal from the condenser microphone 100 is applied and a non-inverting input terminal (+) to which a direct current bias voltage is applied, a feedback capacitor 103 connected between the inverting input terminal (−) and an output terminal 102 of the operational amplifier 101, a feedback resistor 104 connected between the inverting input terminal (−) and the output terminal 102 of the operational amplifier 101, and a microphone bias voltage source 105 that provides the condenser microphone 100 with a direct current bias voltage.

A parasitic capacitance due to a pad, a gate capacitance of an initial stage transistor and the like of an integrated circuit is attached to each of the two input terminals of the operational amplifier 101. The parasitic capacitance is represented by a parasitic capacitor 106 connected with the inverting input terminal (−).

The non-inverting input terminal (+) of the operational amplifier 101 shown in FIG. 1 is connected with a direct current bias voltage source 107. The operational amplifier 101 performs feedback operation through the feedback resistor 104 so that a voltage at the inverting input terminal (−) becomes equal to a voltage at the non-inverting input terminal (+).

As a result, the voltage at the inverting input terminal (−) of the operational amplifier 101 is kept constant. Even when a change in the signal propagates from the condenser microphone 100, the change does not cause a variation in the voltage at the inverting input terminal (−).

Next, a total gain of the operational amplifier 101 will be figured out. The total gain G of the microphone amplifier shown in FIG. 1 is represented by the following equation (1):
G=C1/{C3+(C1+C2+C3)/A} (1)
where,

C1: capacitance of the condenser microphone 100

C2: capacitance of the parasitic capacitor 106

C3: capacitance of the feedback capacitor 103

A: open loop gain of the operational amplifier 101.

It is assumed that the resistance of the feedback resistor 104 is large enough to be ignored against the signal. Assuming that the open loop gain A is infinitely large, the equation (1) is modified into the following equation (2):
G=C1/C3 (2)

Note that a term of the capacitance C2 is eliminated in the equation (2). Because a signal influenced by the parasitic capacitor 106 is not generated at the inverting input terminal (−) of the operational amplifier 101 and because the total gain of the operational amplifier 101 does not include the term of the capacitance C2, an audio signal that is not influenced by the parasitic capacitor 106 can be obtained from the output terminal 102 of the operational amplifier 101. As understood from the equation (1) and FIG. 1, a feedback signal is fed back through the feedback capacitor 103 in the embodiment of this invention.

Because of the connection described above, the capacitance C2 of the parasitic capacitor 106 can be reduced to 1/A. Since an apparent capacitance of the parasitic capacitor 106 is reduced to the very small value as described above, the sensitivity of the microphone is not reduced. When the sensitivity of the microphone is not reduced, there is no need to increase the total gain G of the microphone amplifier. Thus, generation of the floor noise can be reduced.

As described above, the influence of the parasitic capacitance of the operational amplifier can be significantly reduced with the microphone amplifier according to the embodiment of this invention. Also, since the voltage signal from the condenser microphone is not attenuated by the influence of the parasitic capacitance, there is no need to increase the gain of the operational amplifier, and thus the generation of the floor noise is reduced to improve an S/N ratio.

In addition, the total gain of the microphone amplifier can be set according to a ratio of the capacitance of the condenser microphone to the capacitance of the feedback capacitor.

The influence of the parasitic capacitance of the operational amplifier can be significantly reduced with the microphone amplifier according to the embodiment of this invention.

Also, there is no need to increase the gain of the operational amplifier, and thus the generation of the floor noise is reduced to improve the S/N ratio with the microphone amplifier according to the embodiment of this invention, since the voltage signal from the condenser microphone is not attenuated by the influence of the parasitic capacitance. In other words, the sensitivity of the microphone is enhanced.

In addition, according to the embodiment of this invention, the total gain of the microphone amplifier can be set in accordance with the ratio of the capacitance of the condenser microphone to the capacitance of the feedback capacitor.

What is claimed is:

1. A microphone amplifier comprising:
a condenser microphone that converts a sound into a voltage signal;
an operational amplifier comprising an inverting input terminal to which the voltage signal from the condenser microphone is applied and a non-inverting input terminal to which a direct current bias voltage is applied;
a capacitor connected between the inverting input terminal and an output terminal of the operational amplifier; and
a resistor connected between the inverting input terminal and the output terminal of the operational amplifier.

2. The microphone amplifier of claim 1, further comprising a parasitic capacitance generated at the inverting input terminal of the operational amplifier, wherein the higher an open loop gain of the operational amplifier is, the less the parasitic capacitance has an effect on a total gain of the operational amplifier.

3. The microphone amplifier of claim 1, wherein a total gain of the operational amplifier is determined in accordance with a ratio of a capacitance of the condenser microphone to a capacitance of the capacitor.
